(19) United States
(12) Patent Application Publication
(10) Pub. No.: US 2007/0170949 A1
(43) Pub. Date: Jul. 26, 2007

(54) DISPLAY DEVICE, LIQUID CRYSTAL DISPLAY PANEL ASSEMBLY, AND TESTING METHOD OF DISPLAY DEVICE

(75) Inventors: Sang-Jin PAK, Yongin-si (KR); Myung-Woo LEE, Seoul (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/624,366

(22) Filed: Jan. 18, 2007

(30) Foreign Application Priority Data
Jan. 23, 2006 (KR) 10-2006-0006733

(51) Int. Cl. G01R 31/00

(52) U.S. Cl. 324/770

(57) ABSTRACT

A display device having a sensing unit includes a first substrate having a plurality of test spacers, and a second substrate having a plurality of sensing unit test lines facing the test spacers, respectively. The surface heights of the sensing unit test lines are different from each other. The heights of the test spacers are substantially the same. The second substrate further includes a plurality of height difference portions formed under the sensing unit test lines, and the number of height difference portions formed under the sensing unit test lines is different for different sensing unit test lines.

This application claims priority to Korean Patent Application No. 10-2006-0006733, filed on Jan. 23, 2006, and all the benefits accruing therefrom under 35 U.S.C. §119, the contents of which in its entirety are herein incorporated by reference.

### BACKGROUND OF THE INVENTION

(a) Field of the Invention

The present invention relates to a display device, a liquid crystal panel assembly, and a testing method of the display device. More particularly, the present invention relates to a display device having sensor units, a liquid crystal panel assembly, and a testing method of the sensor units of the display device.

(b) Description of the Related Art

Liquid crystal displays (“LCDs”) include a pair of panels provided with pixel electrodes and a common electrode, and a liquid crystal layer with dielectric anisotropy interposed between the panels. The pixel electrodes are arranged in a matrix and connected to switching elements such as thin film transistors (“TFTs”) such that they receive image data voltages row by row. The common electrode covers the entire surface of one of the two panels, and is supplied with a common voltage. A pixel electrode and corresponding portions of the common electrode, and corresponding portions of the liquid crystal layer, form a liquid crystal capacitor that, along with a switching element connected thereto, is a basic element of a pixel.

LCDs generate electric fields by applying voltages to the pixel electrodes and the common electrode, and varies the strength of the electric fields to adjust the transmittance of light passing through the liquid crystal layer to thereby display images. Touch screen panels write or draw letters or pictures by touching a finger, touch pen, or a stylus to a display panel, or carry out desired operations of machines such as computers, etc., by operating icons. LCDs attached to the touch screen panels determine whether and where a touch occurs on the display panel. However, the manufacturing cost of the LCD increases due to the attached touch screen panel. Furthermore, due to the addition of a process for attaching the touch screen panel to the LCD, the yield and the luminance decrease and the thickness of the LCD increases.

For solving the above problems, a plurality of sensing units, which are implemented with the TFTs, are integrated into the LCD. The sensing unit senses the variation of light incident upon the display panel by a touch of the finger of a user, etc., to determine whether and where a touch occurs.

For testing the operations of the sensing units integrated into the LCD, after operating the sensing units by applying pressure, etc., from the outside, test signals are applied to the sensing units by contacting a test pin of a test device to each of test pads, thereby testing the operating state of the LCD.

Therefore, much test time is required due to difficulties such as contacting the test pin to the test pads of a small size, and the testing is regarded as a troublesome job.

### BRIEF SUMMARY OF THE INVENTION

The present invention solves the problems of the conventional techniques described above by providing a display device having sensor units, a liquid crystal panel assembly, and a testing method of the sensor units of the display device, where a test result of the sensors is determined through pixels of the display device.

A display device according to exemplary embodiments of the present invention includes a first substrate having a plurality of test spacers, and a second substrate having a plurality of sensing unit test lines facing the test spacers, respectively. The surface heights of the sensing unit test lines are different from each other. The heights of the test spacers may be the same.

The second substrate may further include a plurality of height difference portions formed under the sensing unit test lines, and the number of height difference portions formed under the sensing unit test lines may be different for different sensing unit test lines. The test spacers may include first to third test spacers, the sensing unit test lines may include first to third sensing unit test lines facing the first to third test spacers, respectively, the height difference portions may include first to third height difference portions, the first height difference portion may be formed under the first sensing unit test line, the first and second height difference portions may be formed under the second sensing unit test line, and the first to third height difference portions may be formed under the third sensing unit test line.

The first substrate may further include a conductor formed on the test spacers, and a distance between a surface of the conductor formed on the first test spacer and a surface of the first sensing unit test line may be larger than 0 Å. A distance between a surface of the conductor formed on the second test spacer and a surface of the second sensing unit test line and a distance between a surface of the conductor formed on the third test spacer and a surface of the third sensing unit test line may be substantially 0 Å.

The first substrate may further include a contact sensing protrusion formed adjacent to the test spacers, the second substrate may further include a sensing data line facing the contact test protrusion, and a surface height of the sensing data line may be substantially the same as one of the surface heights of the sensing unit test lines. The surface height of the sensing data line may be substantially the same as the surface height of the first sensing unit test line.

The second substrate may further include a fourth height difference portion formed under the sensing data line, and the fourth height difference portion may be formed on a same layer of the second substrate as the first height difference portion.

A height of the contact sensing protrusion may be the same as heights of the test spacers.

The second substrate may further include a plurality of image scanning line, an insulating layer formed on the image scanning lines and the first height difference portion, a semiconductor layer formed on the insulating layer, a plurality of image data lines on the semiconductor layer, and a passivation layer formed on the image data lines, the third height difference portion, an exposed portion of the second height difference portion, and an exposed portion of the insulating layer.

The first height difference portion may be formed on a same layer of the second substrate as the image scanning line, the second height difference portion may be formed on a same layer of the second substrate as the semiconductor layer, and the third height difference portion may be formed on a same layer of the second substrate as the image data lines.

A thickness of the passivation layer formed under the first to third sensing unit test lines may be substantially equal.

The second substrate may further include a fourth height difference portion formed on the second height difference portion and an ohmic contact formed on the semiconductor layer, and the fourth height difference portion and the ohmic contact may be formed within a same layer of the second substrate. The fourth height difference portion and the third height difference portion may have the same boundary.

The second substrate may further include a plurality of signal transmitting units connected to the sensing unit test lines, respectively, a signal input line supplied with a control signal controlling the signal transmitting units from an external device, and a plurality of pixel test lines connected to the signal transmitting units, respectively. The display device may further include a plurality of pixels connected to the pixel test lines.

Pixels representing a same color may be connected to a same pixel test line. The signal input line may include a first pad inputting the control signal, and the pixel test lines may include second test pads inputting pixel test signals from an external device, respectively.

A liquid crystal panel assembly according to other exemplary embodiments includes a plurality of test spacers, a plurality of sensing unit test lines facing the respective test spacers, a plurality of signal transmitting units connected to the sensing unit test lines, respectively, a signal input line that is supplied with a control signal controlling the signal transmitting units from an external device, a plurality of pixel test lines connected to the signal transmitting units, respectively, and a plurality of pixels connected to the pixel test lines. Surface heights of the sensing unit test lines may be different from each other.

The heights of the test spacers may be the same.

The liquid crystal panel assembly may further include a plurality of height difference portions formed under the sensing unit test lines. The number of height difference portions formed under the sensing unit test lines may be different for different sensing unit test lines.

The test spacers may include first to third test spacers, the sensing unit test lines may include first to third sensing unit test lines facing the first to third test spacers, respectively, the height difference portions may include first to third height difference portions, the first height difference portion may be formed under the first sensing unit test line, the first and second height difference portions may be formed under the second sensing unit test line, and the first to third height difference portions may be formed under the third sensing unit test line.

The liquid crystal panel assembly may further include a conductor formed on the test spacers, and a distance between a surface of the conductor formed on the first test spacer and a surface of the first sensing unit test line may be larger than 0 Å. A distance between a surface of the conductor formed on the second test spacer and a surface of the second sensing unit test line and a distance between a surface of the conductor formed on the third test spacer and a surface of the third sensing unit test line may be substantially 0 Å.

The liquid crystal panel assembly may further include a contact sensing protrusion formed adjacent to the test spacers, a sensing data line facing the contact sensing protrusion, and a surface height of the sensing data line may be substantially the same as one of the surface heights of the sensing unit test lines. The surface height of the sensing data line may be substantially the same as the surface height of the first sensing unit test line.

The liquid crystal panel assembly may further include a fourth height difference portion formed under the sensing data line. The fourth height difference portion may be formed on a same layer of the second substrate as the first difference portion. A height of the contact sensing protrusion may be the same as a height of the test spacers.

Pixels representing a same color may be connected to a same pixel test line.

The signal input line may include a first pad inputting the control signal, the pixel test lines may include second test pads inputting pixel test signals from an external device, respectively, and the first and second test pads may be formed on an exposure region of the liquid crystal panel assembly.

The sensing unit test lines and the signal transmitting units may be formed on an edge region of the liquid crystal panel assembly. The signal transmitting units may be switching elements. The liquid crystal panel assembly may further a cutting line separating a connection between the pixels and the pixel test lines.

A testing method according to further exemplary embodiments is a testing method of a display device, the display device having a plurality of test spacers, a plurality of sensing unit test lines facing the test spacers, respectively, and having different surface heights, a plurality of switching elements respectively connected to the sensing unit test lines, signal input lines supplied with a control signal from an external device to control the switching elements, a plurality of pixel test lines connected to the switching elements, and a plurality of pixels connected to the pixel test lines. The method includes applying a signal turning off the switching elements to the signal input lines, applying first test signals to the pixel test lines to test the pixels, stopping the application of the first test signals and applying a signal turning-on the switching elements to the signal input lines, testing the pixels, and cutting a connection between the pixels and the pixel test lines.

### BRIEF DESCRIPTION OF THE DRAWINGS

Features and advantages of the present invention will be made apparent by describing exemplary embodiments of the present invention with reference to the accompanying drawings, in which:

FIG. 1 is a block diagram of an exemplary LCD according to an exemplary embodiment of the present invention;

FIG. 2 is an equivalent circuit diagram of one pixel of an exemplary LCD according to an exemplary embodiment of the present invention;

FIG. 3 is a block diagram of an exemplary LCD showing exemplary sensing units according to an exemplary embodiment of the present invention;

FIG. 4 is an equivalent circuit diagram of an exemplary pressure sensor of an exemplary LCD according to an exemplary embodiment of the present invention;

FIG. 5 is a schematic diagram of an exemplary LCD according to an exemplary embodiment of the present invention;

FIG. 6 is a schematic diagram of a portion of an exemplary liquid crystal panel assembly with a plurality of wires and a plurality of switching elements for testing pixels and pressure sensors according to an exemplary embodiment of the present invention;

FIG. 7 is a layout view of an exemplary TFT array panel of an exemplary LCD according to an exemplary embodiment of the present invention;

FIG. 8 is a layout view of an exemplary common electrode panel of an exemplary LCD according to an exemplary embodiment of the present invention;

FIG. 9 is a layout view of an exemplary LCD having the exemplary panels shown in FIGS. 7 and 8;

FIG. 10 is a sectional view of the exemplary LCD shown in FIG. 9 taken along line X-X;

FIG. 11 is a sectional view of the exemplary LCD shown in FIG. 9 taken along line XI-XI; and,

FIG. 12 is a sectional view of the exemplary liquid crystal panel assembly shown in FIG. 6 taken along line XII-XII.

### DETAILED DESCRIPTION OF THE INVENTION

The present invention will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Now, an LCD, which is an exemplary embodiment of a display device according to the present invention, will be described in detail with reference to the drawings.

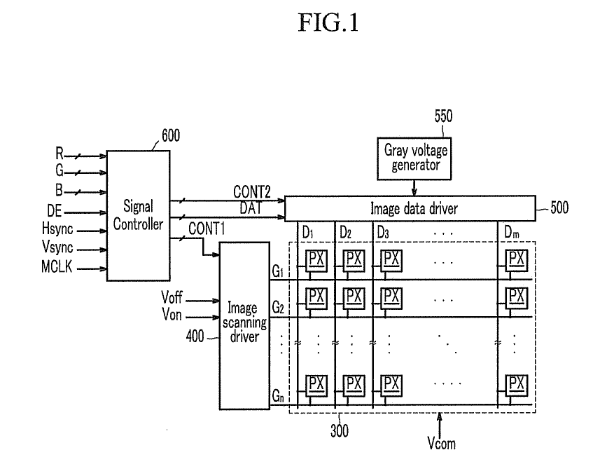

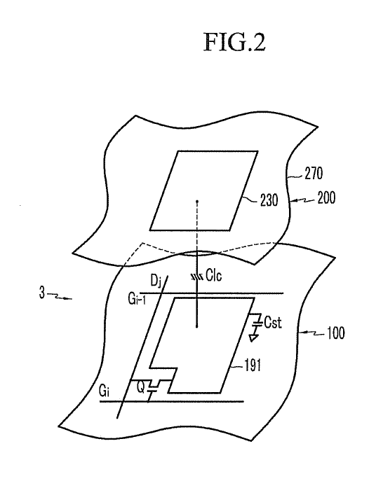

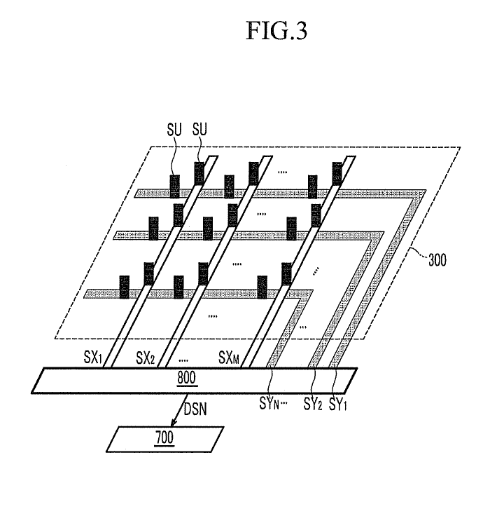

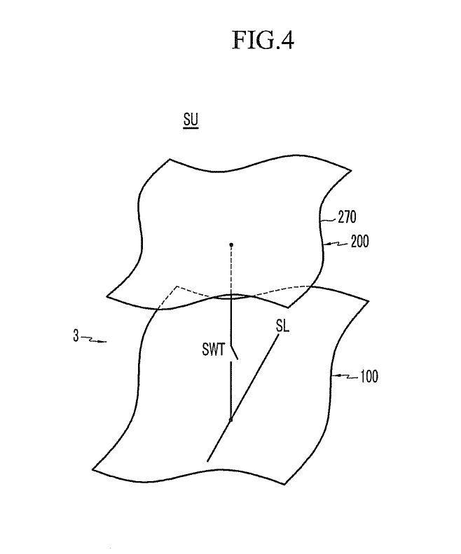

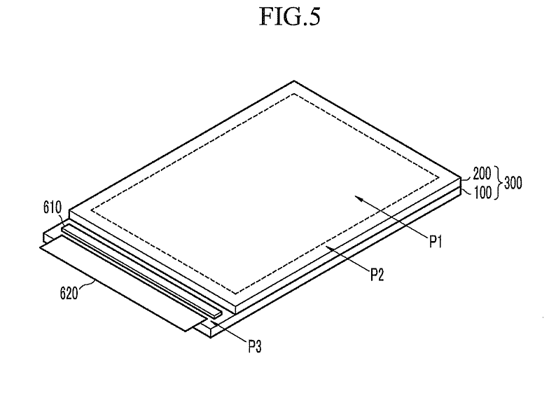

FIG. 1 is a block diagram of an exemplary LCD according to an exemplary embodiment of the present invention, and FIG. 2 is an equivalent circuit diagram of one pixel of an exemplary LCD according to an exemplary embodiment of the present invention. FIG. 3 is a block diagram of an exemplary LCD showing exemplary sensing units according to an exemplary embodiment of the present invention, and FIG. 4 is an equivalent circuit diagram of an exemplary pressure sensor of an exemplary LCD according to an exemplary embodiment of the present invention. FIG. 5 is a schematic diagram of an exemplary LCD according to an exemplary embodiment of the present invention.

Referring to FIGS. 1 to 3, the LCD according to an exemplary embodiment of the present invention includes a liquid crystal (“LC”) panel assembly 300 and an image scanning driver 400 that is connected thereto, an image data driver 500, a sensing signal processor 800, a gray voltage generator 550 that is connected to the image data driver 500, a contact determiner 700 that is connected to the sensing signal processor 800, and a signal controller 600 that controls the above described elements.

Referring to FIGS. 1 to 4, the liquid crystal panel assembly 300 includes a plurality of display signal lines G₁-Gₙ and D₁-Dₘ, a plurality of pixels PX that are connected thereto and that are arranged in approximately a matrix shape, and a plurality of sensing signal lines SY₁-SY_{N} and SX₁-SX_{M} and a plurality of sensors SU that are connected thereto and that are also arranged in approximately a matrix shape. Further, referring to FIGS. 2 and 5, the liquid crystal panel assembly 300 includes a TFT array panel 100 and a common electrode panel 200 that are opposite to each other, a liquid crystal layer 3 that is interposed there between, and a spacer (not shown) that maintains a gap between the two display panels 100 and 200 and that can be deformed to some extent by compression.

The display signal lines G₁-Gₙ and D₁-Dₘ include a plurality of image scanning lines G₁-Gₙ, also known as gate lines, that transfer an image scanning signal and image data lines D₁-Dₘ that transfer an image data signal. The sensing signal lines SY₁-SY_{N} and SX₁-SX_{M} include a plurality of vertical sensing data lines SX₁-SX_{M} and a plurality of horizontal sensing data lines SY₁-SY_{N} that transfer sensing data signals.

The image scanning lines G₁-Gₙ and the horizontal sensing data lines SY₁-SY_{N} extend in approximately a row direction, a first direction, and are almost parallel to each other, and the image data lines D₁-Dₘ and the vertical sensing data lines SX₁-SX_{M} extend in approximately a column direction, a second direction, and are almost parallel to each other. The first direction may be substantially perpendicular to the second direction.

Each of the pixels PX includes a switching element Q that is connected to the display signal lines G₁-Gₙ and D₁-Dₘ, and a storage capacitor Cst and a liquid crystal capacitor Clc that are connected thereto. In alternative embodiments, the storage capacitor Cst may be omitted as necessary.

The switching element Q is a three terminal element such as a TFT that is provided on the TFT array panel 100, and a control terminal, such as a gate electrode, thereof is connected to the image scanning lines G₁-Gₙ, an input terminal, such as a source electrode, thereof is connected to the image data lines D₁-Dₘ, and an output terminal, such as a drain electrode, thereof is connected to the liquid crystal capacitor Clc and the storage capacitor Cst. The TFT also includes amorphous silicon (“a-Si”) or polycrystalline silicon.

The liquid crystal capacitor Clc includes a pixel electrode 191 of the TFT array panel 100 and a common electrode 270 of the common electrode panel 200 as two terminals, and the liquid crystal layer 3 between the two electrodes 191 and 270 functions as a dielectric material. The pixel electrode 191 is connected to the switching element Q, and the common electrode 270 is formed on an entire surface, or substantially an entire surface, of the common electrode panel 200 and receives a common voltage Vcom.

In an alternative embodiment, the common electrode 270 may be provided on the TFT array panel 100, and in such a case, at least one of the two electrodes 191 and 270 may be formed in a line shape or a bar shape.

The storage capacitor Cst as an assistant of the liquid crystal capacitor Clc is formed with the overlap of a separate signal line (not shown) and the pixel electrode 191 that is provided in the TFT array panel 100 with an insulator interposed there between, and a predetermined voltage such as a common voltage Vcom is applied to the separate signal line. However, the storage capacitor Cst may be formed with the overlap of the pixel electrode 191 and a previous image scanning line directly on the electrode 191 via an insulator.

In order to represent color display, by allowing each pixel PX to inherently display one color in a set of colors, such as primary colors, (spatial division) or to sequentially display the colors in the set of colors (temporal division), a desired color is recognized with the spatial and temporal sum of the colors. An example of a set of the colors includes red, green, and blue. FIG. 2 shows as an example of spatial division in which each pixel PX is provided with a color filter 230 for displaying one of the colors in a region of the common electrode panel 200 corresponding to the pixel electrode 191. Alternatively, the color filter 230 may be formed on or under the pixel electrode 191 of the TFT array panel 100.

At least one polarizer (not shown) for polarizing light is attached to the outside surface of the liquid crystal panel assembly 300. For example, first and second polarized films may be disposed on the TFT array panel 100 and the common electrode panel 200, respectively. The first and second polarized may adjust a transmission direction of light externally provided into the TFT array panel 100 and the common electrode panel 200, respectively, in accordance with an aligned direction of the liquid crystal layer 3. The first and second polarized films may have first and second polarized axes thereof substantially perpendicular to each other, respectively. In a reflective LCD, one of the first and second polarized films may be eliminated.

The sensor SU may have a structure shown in FIG. 4. The sensor SU that is shown in FIG. 4 is a pressure sensor including a switch SWT that is connected to horizontal and vertical sensing data lines SL (hereinafter referred to as a “sensing data lines”).

The switch SWT has the common electrode 270 of the common electrode panel 200 and a sensing data line SL of the TFT array panel 100 as two terminals, and at least one of the two terminals is protruded, whereby the two terminals are physically and electrically connected to each other by a user. Accordingly, a common voltage Vcom from the common electrode 270 is output to a sensing data line SL as a sensing data signal.

FIG. 3 schematically shows the sensors SU formed by the construction of the common electrode panel 200 and the TFT array panel 100 as shown in FIG. 4.

The contact determiner 700 determines Y-coordinates of contact points by making an analysis of the horizontal sensing data signals transmitted by the horizontal sensing data lines SY₁-SY_{N}, and X-coordinates of the contact points by making an analysis of the vertical sensing data signals transmitted by the vertical sensing data lines SX₁-SX_{M}.

Each pressure sensor SU is disposed between two adjacent pixels PX. The density of a pair of sensors SU, each of which is connected to the horizontal and vertical sensing data lines SY₁-SY_{N} and SX₁-SX_{M} and that are adjacently disposed in an intersecting region thereof, may be, for example, about ¼ of the dot density. Here, one dot includes, for example, three pixels PX that are arranged parallel to each other and that display three colors such as red, green, and blue. One dot displays one color and becomes a basic unit that displays resolution of the LCD. However, one dot may be composed of at least four pixels PX, and in this case each pixel PX may display one of three colors and one white color.

Examples in which the density of a pair of sensors SU is ¼ of the dot density include a case where the horizontal and vertical resolution of a pair of sensors SU is ½ of the horizontal and vertical resolution of the LCD, respectively. In this case, there may be a pixel row and a pixel column where there is no sensor SU.

If the density of the sensor SU and the dot density are set to this degree, the LCD can be applied to an application field requiring high accuracy, such as character recognition. In alternative embodiments, the resolution of the sensor SU may be higher or lower, as necessary.

Referring again to FIGS. 1 and 3, the gray voltage generator 550 generates two gray voltage sets (or a reference gray voltage set) related to transmittance of the pixels PX. One of the two sets has a positive value for a common voltage Vcom, and the other set has a negative value.

The image scanning driver 400 is connected to the image scanning lines G₁-Gₙ of the liquid crystal panel assembly 300 to apply an image scanning signal including a combination of a gate-on voltage Von for turning on the switching element Q and a gate-off voltage Voff for turning off the switching element Q to the image scanning lines G₁-Gₙ.

The image data driver 500 is connected to the image data lines D₁-Dₘ of the liquid crystal panel assembly 300, and it selects a gray voltage from the gray voltage generator 550 and applies the voltage as an image scanning signal to the image data lines D₁-Dₘ. However, when the gray voltage generator 550 does not supply a voltage for all grays but supplies only a predetermined number of reference gray voltages, the image data driver 500 divides the reference gray voltages, generates gray voltages for all grays, and selects an image data signal from among them.

The sensing signal processor 800 is connected to the sensing data lines SY₁-SY_{N} and SX₁-SX_{M} of the liquid crystal panel assembly 300 to receive a sensing data signal that is output through the sensing data lines SY₁-SY_{N} and SX₁-SX_{M}, and performs signal processing and generation of digital sensing signals DSN.

The contact determiner 700 may be composed of a central processor unit (“CPU”), etc., and it receives a digital sensing signal DSN from the sensing signal processor 800 to determine a contact position of the pressure sensor SU.

The signal controller 600 controls an operation of the image scanning driver 400, the image data driver 500, the gray voltage generator 550, the sensing signal processor 800, etc.

Each of the driving devices 400, 500, 550, 600, 700, and 800 may be directly mounted on the liquid crystal panel assembly 300 in a form of at least one integrated circuit (“IC”) chip, mounted on a flexible printed circuit (“FPC”) film (not shown) to be attached to the liquid crystal panel assembly 300 in a form of a tape carrier package (“TCP”), or mounted on a separate printed circuit board (“PCB”) (not shown). Alternatively, the driving devices 400, 500, 550, 600, 700, and 800, the signal lines G₁-Gₙ, D₁-Dₘ, SY₁-SY_{N}, and SX₁-SX_{M}, and the TFT Q, etc., may be integrated with the liquid crystal panel assembly 300.

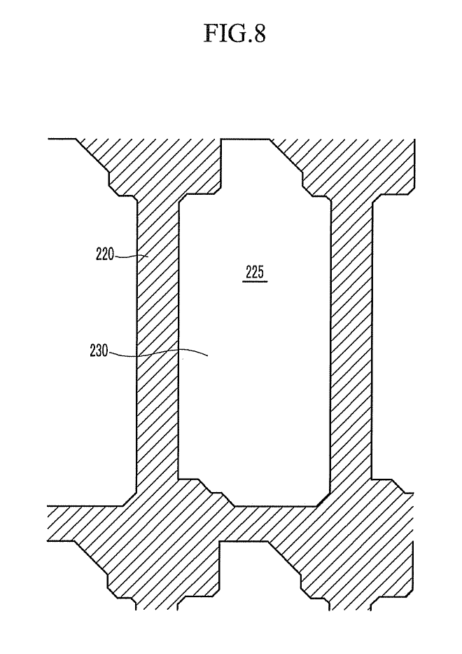

Referring to FIG. 5, the liquid crystal panel assembly 300 is divided into a display region P1, an edge region P2, and an exposure region P3. Most of the pixels PX, the sensors SU, and the signal lines G₁-Gₙ, D₁-Dₘ, SY₁-SY_{N}, and SX₁-SX_{M} are positioned in the display region P1. The common electrode panel 200 includes a light blocking member 220, as shown in FIG. 8, and the light blocking member 220 covers most of the edge region P2 to block light from the outside. The common electrode panel 200 is smaller than the TFT array panel 100, and thus exposes a part of the TFT array panel 100, thereby forming the exposure region P3. A single chip 610 is mounted in the exposure region P3, and an FPC board 620 is attached to the exposure region P3.

The single chip 610 includes the driving devices, i.e., the image scanning driver 400, the image data driver 500, the gray voltage generator 550, the signal controller 600, the contact determiner 700, and the sensing signal processor 800 for driving the LCD. By integrating the driving devices 400, 500, 550, 600, 700, and 800 in the single chip 610, the mounting area thereof can be reduced and power consumption can be lowered. If necessary, at least one of the driving devices or at least one circuit element constituting at least one of the driving devices may be disposed outside of the single chip 610.

The image signal lines G₁-Gₙ and D_{I}-Dₘ and the sensing data lines SY₁-SY_{N} and SX₁-SX_{M} are extended up to the exposure area P3 to connect to the corresponding driving devices 400, 500, and 800.

The FPC board 620 receives a signal from the outside devices to transfer to the single chip 610 or the liquid crystal panel assembly 300, and an end tip thereof is composed of a connector (not shown) in order to easily connect to outside apparatuses.

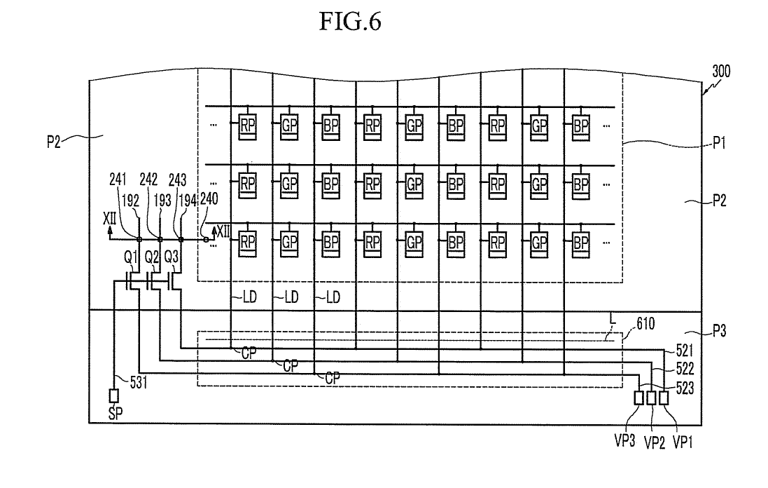

FIG. 6 is a schematic diagram of a portion of a liquid crystal panel assembly with a plurality of wires and a plurality of switching elements for testing pixels and pressure sensors according to an exemplary embodiment of the present invention.

As shown in FIG. 6, a plurality of signal lines 521-523, 192-194, and 531 such as inspection lines, test lines, and signal input lines, and a plurality of switching elements Q1-Q3 for testing pixels PX, test spacers 241, 242, and 243, and the pressure sensors SU are formed on the LC panel assembly 300.

The configuration of the signal lines 521-523, 192-194, and 531 and the switching elements Q1-Q3 will now be described.

As shown in FIG. 6, the single chip 610 is mounted on the exposure region P3 positioned on the front or rear portion of the LC panel assembly 300, as described above.

A plurality of visual inspection (“VI”) lines 521-523 are formed under the single chip 610. The VI lines 521-523 are connected to the image data lines LD that are connected to a plurality of columns of red pixels (“RP”), a plurality of columns of green pixels (“GP”), and a plurality of columns of blue pixels (“BP”), via contact portions CPs, respectively.

As illustrated, the VI line 521 is connected to the red pixel columns to test the red pixels RP, the VI line 522 is connected to the green pixel columns to test the green pixels GP, and the VI line 523 is connected to the blue pixel columns to test the blue pixels BP. However, the connections between the VI lines 521-523 and the pixels RP, GP, and BP may be varied.

The VI lines 521-523 are arranged in parallel to each other, and each of the VI lines 521-523 mainly extends in a horizontal direction, the first direction, and then one end of each of the VI lines 521-523 extends in a longitudinal direction, for example in a downward direction or second direction pointing away from the display region P1. The respective VI lines 521-523 have test pads VP1-VP3 connected to the ends thereof.

The other end of each VI line 521-523 extends in the opposite direction with respect to the corresponding end, for example in an upward direction, to reach the edge region P2.

The test signal input line 531 is formed in the exposure region P3. The test signal input line 531 has a test pad SP that is formed at one end thereof, and extends in the longitudinal direction, for example in the upward direction or second direction pointing towards the edge region P2, to reach the edge region P2.

The switching elements Q1-Q3, for example TFTs having three terminals, are formed in the edge region P2. The output terminals, such as drain electrodes, of the switching elements Q1-Q3 are connected to the ends of the respective test signal input lines 531-523 extended from the exposure region P3 to the edge region P2, and the control terminals, such as gate electrodes, of the switching elements Q1-Q3 are connected to the test signal input line 531. The input terminals, such as source electrodes, of the switching elements Q1-Q3 are connected to the pressure sensor test lines 192-194 that are formed in the edge region P2.

The switching elements Q1-Q3 are formed along with the switching elements Q of the pixels PX, and may be a-Si or polysilicon TFTs.

The test spacers 241, 242, and 243 may be formed with the common electrode panel 200, and will be further described below.

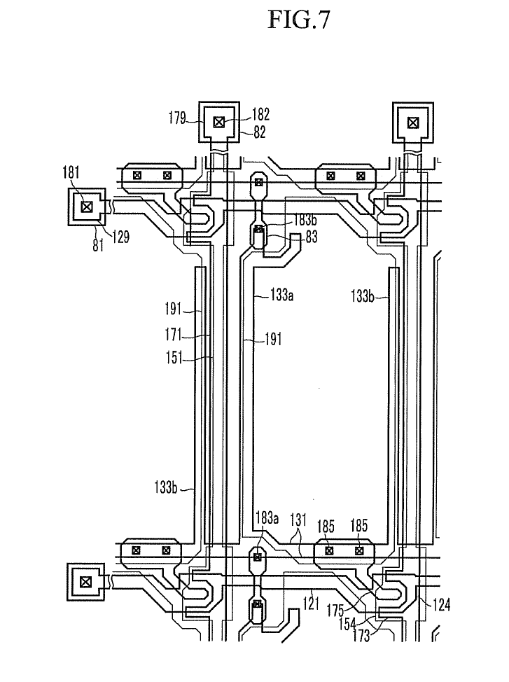

Next, an LCD including the TFT array panel 100 and the common electrode panel 200 according to an exemplary embodiment of the present invention will be described with reference to FIGS. 7-12.

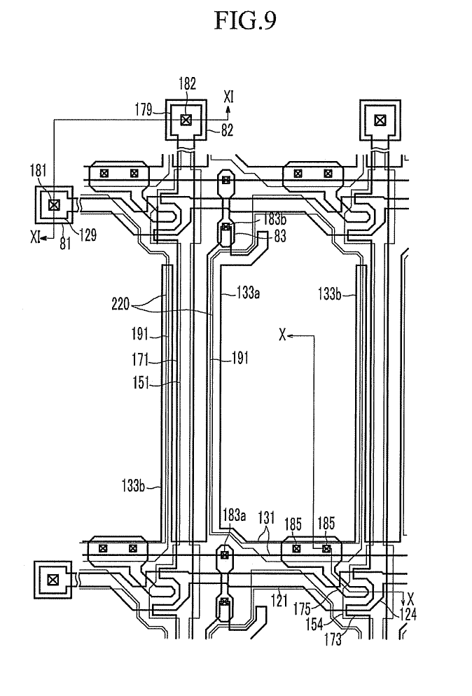

FIG. 7 is a layout view of an exemplary TFT array panel for an exemplary LCD according to an exemplary embodiment of the present invention, and FIG. 8 is a layout view of an exemplary common electrode panel for an exemplary LCD according to an exemplary embodiment of the present invention. FIG. 9 is a layout view of an exemplary LCD including the exemplary TFT array panel and the exemplary common electrode panel shown in FIGS. 7 and 8 according to an exemplary embodiment of the present invention.

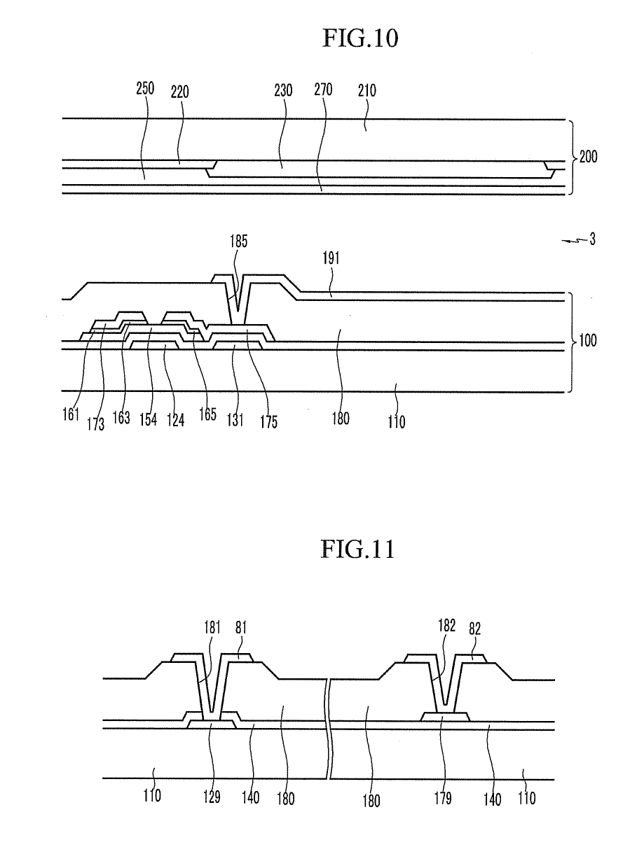

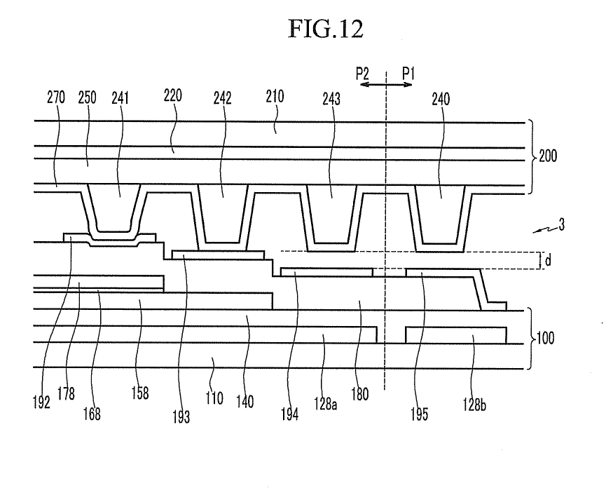

FIG. 10 is a sectional view of the exemplary LCD including the exemplary TFT array panel and the exemplary common electrode panel shown in FIG. 9 taken along line X-X, and FIG. 11 is a sectional view of the exemplary LCD including the exemplary TFT array panel and the exemplary common electrode panel shown in FIG. 9 taken along line XI-XI. FIG. 12 is a sectional view of the exemplary LC panel assembly shown in FIG. 6 taken along line XII-XII.

First, a TFT array panel 100 according to an exemplary embodiment of the present invention will be described in detail with reference to FIGS. 7 and 9 to 12.

A plurality of image scanning lines 121, a plurality of storage electrode lines 131, and first height difference portions 128a and 128b are formed on an insulating substrate 110 made of a material such as, but not limited to, transparent glass or plastic.

The image scanning lines 121 transmit image scanning signals and extend substantially in a transverse direction, such as a first direction. Each of the image scanning lines 121 includes a plurality of gate electrodes 124 projecting downward, towards an adjacent image scanning line 121, and an end portion 129 having a large area for contact with another layer or an external driving circuit. An image scanning driving circuit, such as the image scanning driver 400, for generating the image scanning signals may be mounted on a FPC film (not shown), which may be attached to the substrate 110, directly mounted on the substrate 110, or integrated with the substrate 110. The image scanning lines 121 may extend to be connected to a driving circuit that may be integrated with the substrate 110.

The storage electrode lines 131 are supplied with a predetermined voltage, and each of the storage electrode lines 131 includes a stem extending substantially parallel to the image scanning lines 121 and a plurality of pairs of first and second storage electrodes 133a and 133b branched from the stems. Each of the storage electrode lines 131 is disposed between two adjacent image scanning lines 121, and the stem of each of the storage electrode lines 131 is disposed close to one of the two adjacent image scanning lines 121. Each of the storage electrodes 133a and 133b has a fixed end portion connected to the stem and a free end portion disposed opposite thereto. The fixed end portion of the first storage electrode 133a has a large area, and the free end portion thereof is bifurcated into a linear branch and a curved branch. However, the storage electrode lines 131 may have various shapes and arrangements.

The first height difference portion 128a may be formed in the edge region P2, but the first height difference portion 128b may be formed in the display region P1.

The image scanning lines 121, the storage electrode lines 131, and the first height difference portions 128a and 128b may be preferably made of an aluminum Al-containing metal such as Al and an Al alloy, a silver Ag-containing metal such as Ag and an Ag alloy, a copper Cu-containing metal such as Cu and a Cu alloy, a molybdenum Mo-containing metal such as Mo and a Mo alloy, chromium Cr, tantalum Ta, or titanium Ti. However, they may have a multi-layered structure including two conductive films (not shown) having different physical characteristics. In such a multi-layered structure, one of the two films may be made of a low resistivity metal such as an Al-containing metal, an Ag-containing metal, and a Cu-containing metal for reducing signal delay or voltage drop, while the other film may be made of a material such as a Mo-containing metal, Cr, Ta, or Ti, which have good physical, chemical, and electrical contact characteristics with other materials such as indium tin oxide (“ITO”) or indium zinc oxide (“IZO”). Good examples of the combination of the two films include a lower Cr film and an upper Al (alloy) film, and a lower Al (alloy) film and an upper Mo (alloy) film. However, while particular examples have been described, the image scanning lines 121, the storage electrode lines 131, and the first height difference portions 128a and 128b may be made of various metals or conductors.

The lateral sides of the image scanning lines 121 and the storage electrode lines 131 are inclined relative to a surface of the substrate 110, and the inclination angle thereof is in a range of about 30 to about 80 degrees. Unlike in FIG. 12, the lateral sides of the first height difference portions 128a and 128b may also be inclined relative to a surface of the substrate 110, and the inclination angle thereof may be in a range of about 30 to about 80 degrees.

An insulating layer 140 preferably made of silicon nitride (SiNx) or silicon oxide (SiOx) is formed on the image scanning lines 121, the storage electrode lines 131, and the height difference portions 128a and 128b, as well as on exposed portions of the insulating substrate 110.

A plurality of semiconductor stripes 151 and a second height difference portion 158 preferably made of hydrogenated a-Si or polysilicon are formed on the insulating layer 140.

The semiconductor stripes 151 extend substantially in the longitudinal direction and become wide near the image scanning lines 121 and the storage electrode lines 131 such that the semiconductor stripes 151 cover large areas of the image scanning lines 121 and the storage electrode lines 131. Each of the semiconductor stripes 151 includes a plurality of projections 154 branched out toward the gate electrodes 124.

The second height difference portion 158 is formed in the edge region P2. The second height difference portion 158 may overlap the first height difference portion 128a.

A plurality of ohmic contact stripes and islands 161 and 165, and a third height difference portion 168 are formed on the semiconductor stripes 151 and the second height difference portion 158. The ohmic contact stripes and islands 161 and 165 are preferably made of n+ hydrogenated a-Si heavily doped with an N-type impurity such as phosphorous, or they may be made of silicide. Each of the ohmic contact stripes 161 includes a plurality of projections 163, and the projections 163 and the ohmic contact islands 165 are located in pairs on the projections 154 of the semiconductor stripes 151.

The third height difference portion 168 is formed in the edge region P2. The third height difference portion 168 may overlap the first height difference portion 128a and the second height difference portion 158.

The lateral sides of the semiconductor stripes 151 and the ohmic contacts 161 and 165 are inclined relative to the surface of the substrate 110, and the inclination angles thereof are preferably in a range of about 30 to about 80 degrees. The lateral sides of the third height difference portion 168 may also be inclined relative to a surface of the substrate 110, and the inclination angle thereof is in a range of about 30 to about 80 degrees.

A plurality of image data lines 171, a plurality of drain electrodes 175, and a fourth height difference portion 178 are formed on the ohmic contacts 161 and 165, the third height difference portion 168, and the exposed insulating layer 140.

The image data lines 171 transmit image data signals and extend substantially in the longitudinal direction, a second direction, to intersect the image scanning lines 121. Each of the image data lines 171 also intersects the storage electrode lines 131 and runs between adjacent pairs of storage electrodes 133a and 133b. Each of image data lines 171 includes a plurality of source electrodes 173 projecting toward the gate electrodes 124 and being curved like a character C, and an end portion 179 having a large area for contact with another layer or an external driving circuit. An image data driving circuit, such as image data driver 500, for generating the image data signals may be mounted on an FPC film (not shown), which may be attached to the substrate 110, directly mounted on the substrate 110, or integrated with the substrate 110. The image data lines 171 may extend to be connected to a driving circuit that may be integrated with the substrate 110.

The drain electrodes 175 are separated from the image data lines 171 and disposed opposite the source electrodes 173 with respect to the gate electrodes 124. Each of the drain electrodes 175 includes a wide end portion and a narrow end portion. The wide end portion overlaps a storage electrode line 131 and the narrow end portion is partly enclosed by a source electrode 173.

A gate electrode 124, a source electrode 173, and a drain electrode 175 along with a projection 154 of a semiconductor stripe 151 form a TFT having a channel formed in the projection 154 disposed between the source electrode 173 and the drain electrode 175.

The fourth height difference portion 178 may be formed in the edge region P2, and may overlap the first height difference portion 128a, the second height difference portion 158, and the third height difference portion 168.

The image data lines 171, the drain electrodes 175, and the fourth height difference portion 178 may be made of a refractory metal such as Cr, Mo, Ta, Ti, or alloys thereof. However, they may have a multilayered structure including a refractory metal film (not shown) and a low resistivity film (not shown). Good examples of the multi-layered structure include a double-layered structure including a lower Cr/Mo (alloy) film and an upper Al (alloy) film, and a triple-layered structure of a lower Mo (alloy) film, an intermediate Al (alloy) film, and an upper Mo (alloy) film. However, while particular examples are described, the image data lines 171, the drain electrodes 175, and the fourth height difference portion 178 may be made of various metals or conductors.

The image data lines 171 and the drain electrodes 175 have inclined edge profiles, and the inclination angles thereof are in a range of about 30 to about 80 degrees. The lateral sides of the fourth height difference portion 178 may also be inclined relative to a surface of the substrate 110, and the inclination angle thereof is in a range of about 30 to about 80 degrees.

The ohmic contacts 161 and 165, and the third height difference portion 168 are interposed only between the underlying semiconductor stripes 151 and the second height difference portion 158 and the overlying conductors 171 and 175 and the fourth height difference portion 178 thereon, and reduce the contact resistance there between. Although the semiconductor stripes 151 are narrower than the image data lines 171 at most places, the width of the semiconductor stripes 151 becomes large near the image scanning lines 121 and the storage electrode lines 131 as described above, to smooth the profile of the surface, thereby preventing disconnection of the image data lines 171. The semiconductor stripes 151 may have almost the same planar shapes as the image data lines 171 and the drain electrodes 175 as well as the underlying ohmic contacts 161 and 165. However, the semiconductor stripes 151 include some exposed portions, which are not covered with the image data lines 171 and the drain electrodes 175, such as portions located between the source electrodes 173 and the drain electrodes 175 which form a channel portion of the TFTs.

A passivation layer 180 is formed on the image data lines 171, the drain electrodes 175, the fourth height difference portion 178, the exposed portions of the semiconductor stripes 151, and the exposed portions of the second height difference portion 158, and may further be formed on exposed portions of the insulative layer 140. The passivation layer 180 may be made of an inorganic or organic insulator and it may have a substantially flat top surface within the display region P1. The passivation layer 180 may include stepped portions in the edge region P2, as will be further described below. Examples of the inorganic insulator include silicon nitride and silicon oxide. The organic insulator may have photosensitivity and a dielectric constant of less than about 4.0. The passivation layer 180 may include a lower film of an inorganic insulator and an upper film of an organic insulator such that it has the excellent insulating characteristics of the organic insulator while preventing the exposed portions of the semiconductor stripes 151 from being damaged by the organic insulator.

The passivation layer 180 has a plurality of contact holes 182 and 185 exposing the end portions 179 of the image data lines 171 and the drain electrodes 175, respectively. The passivation layer 180 and the gate insulating layer 140 have a plurality of contact holes 181 exposing the end portions 129 of the image scanning lines 121, a plurality of contact holes 183a exposing portions of the storage electrode lines 131 near the fixed end portions of the first storage electrodes 133a, and a plurality of contact holes 183b exposing the linear branches of the free end portions of the first storage electrodes 133a.

A plurality of pixel electrodes 191, a plurality of overpasses 83, and a plurality of contact assistants 81 and 82 are formed on the passivation layer 180. A plurality of pressure sensor test lines 192-194 and sensing data lines 195 are also formed on the passivation layer 180. They may be made of a transparent conductor such as ITO or IZO, or a reflective conductor such as Ag, Al, Cr, or alloys thereof.

The pixel electrodes 191 are physically and electrically connected to the drain electrodes 175 through the contact holes 185 such that the pixel electrodes 191 receive image data voltages from the drain electrodes 175. The pixel electrodes 191 supplied with the image data voltages generate electric fields in cooperation with a common electrode 270 of the opposing common electrode panel 200 supplied with a common voltage, which determine the orientations of liquid crystal molecules (not shown) of a liquid crystal layer 3 disposed between the two panels 100 and 200. A pixel electrode 191 and the common electrode 270 form a liquid crystal capacitor which stores applied voltages after the TFT turns off.

A pixel electrode 191 and a drain electrode 175 connected thereto overlap a storage electrode line 131 including storage electrodes 133a and 133b, and the left and right sides of the pixel electrode 191 are adjacent to the image data lines 171 rather than the storage electrodes 133a and 133b. The pixel electrode 191 and a drain electrode 175 electrically connected thereto and the storage electrode line 131 form a storage capacitor which enhances the voltage storing capacity of the liquid crystal capacitor.

The contact assistants 81 and 82 are connected to the end portions 129 of the scanning image lines 121 and the end portions 179 of the image data lines 171 through the contact holes 181 and 182, respectively. The contact assistants 81 and 82 protect the end portions 129 and 179 and enhance the adhesion between the end portions 129 and 179 and external devices.

The overpasses 83 cross over the image scanning lines 121 and are connected to the exposed portions of the storage electrode lines 131 and the exposed linear branches of the free end portions of the storage electrodes 133b through the contact holes 183a and 183b, respectively, which are disposed opposite each other with respect to the image scanning lines 121. The storage electrode lines 131 including the storage electrodes 133a and 133b along with the overpasses 83 can be used for repairing defects in the image scanning lines 121, the image data lines 171, or the TFTs.

Within the edge region P1, the pressure sensor test line 192 is formed on portions of the TFT array panel 100 on which all of the first to fourth height difference portions 128a, 158, 168, and 178, the insulating layer 140, and the passivation layer 180 are formed. The pressure sensor test line 193 is formed on portions on which the first and second height difference portions 128a and 158, the insulating layer 140, and the passivation layer 180 are formed. The pressure sensor test line 194 is formed on portions on which the first height difference portions 128a, the insulating layer 140, and the passivation layer 180 are formed.

Within the display region P1, the sensing data line 195 is formed on the portions on which the first height difference portion 128b, the insulating layer 140, and the passivation layer 180 are formed.

The thickness of the passivation layer 180 that is formed under the pressure sensor test lines 191-193 is substantially the same as that of the passivation layer that is formed under the sensing data line 195. However, distances from the surface of the substrate 110 to the respective pressure sensor test lines 192-194 and the sensing data line 195 are different from each other. That is, the distances are varied depending on whether or not the height difference portions 128a, 128b, 158, 168, and 178 are formed. For example, the distance from the pressure sensor test line 192, under which the first and fourth height difference portions 28a, 158, 168, and 178 are formed and the surface of the substrate 110 is largest, and the distance from the pressure sensor test line 194, under which only the first height difference portion 128a is formed and the surface of the substrate 110 is smallest. The distance from at least a portion of the sensing data line 195 to the substrate 110 may be about the same as the distance from the pressure sensor test line 194 and the substrate 110.

Now, the common electrode panel 200 will be described with reference to FIGS. 8 to 12.

A light blocking member 220 referred to as a black matrix for preventing light leakage is formed on an insulating substrate 210 made of a material such as, but not limited to, transparent glass or plastic.

The light blocking member 220 has a plurality of openings 225 that face the pixel electrodes 191, and each opening may have substantially the same planar shape as the pixel electrodes 191. The light blocking member 220 prevents light leakage between the pixel electrodes 191.

A plurality of color filters 230 are also formed on the substrate 210, and they are disposed substantially in the areas enclosed by the light blocking member 220. The color filters 230 may extend substantially in the longitudinal direction along the pixel electrodes 191. Each color filter 230 may represent one color in a set of colors such as red, green, and blue colors.

An overcoat 250 is formed on the color filters 230 and the light blocking member 220. The overcoat 250 is preferably made of an (organic) insulator, and it prevents the color filters 230 from being exposed and provides a flat surface. In alternative embodiments, the overcoat 250 may be omitted.

A plurality of test spacers 241-243 and a plurality of contact sensing protrusions 240 are formed on the overcoat 250. Heights of the test spacers 241-243 and the contact sensing protrusions 240 are substantially the same. They may be made of an organic material, etc.

The test spacer 241 faces the pressure sensor test line 192, the test spacer 242 faces the pressure sensor test line 193, and the test spacer 243 faces the pressure sensor testing line 194. The contact sensing protrusions 240 face the corresponding sensing data line 195.

A common electrode 270 is formed on the test spacers 241-243 and the contact sensing protrusions 240, and the exposed overcoat 250. The common electrode 270 may be made of a transparent conductive material such as ITO and IZO.

The common electrode 270 formed on the test spacer 243 and the contact sensing protrusion 240, and the pressure sensing test line 194 and the sensing data line 195 that are opposite to the test spacer 243 and the contact sensing protrusion 240, respectively, are spaced apart by a predetermined distance “d.”

The common electrode 270 formed on the contact sensing protrusion 240 forms a switch SWT along with the opposite sensing data line 195, as previously described with respect to FIG. 4.

By adjusting the distance between the common electrode 270 formed on the test spacer 243 and the pressure sensing test line 194 that faces the common electrode 270, the allowable minimum distance between the contact sensing protrusion 240 and the sensing data line 195 is defined. That is, until the distance between the common electrode 270 formed on the test spacer 243 and the pressure sensor test line 194 becomes about “0 Å”, or in other words until there is no longer a space between the common electrode 270 formed on the test spacer 243 and the pressure sensor test line 194, it is determined that the distance between the common electrode 270 on the contact sensing protrusion 240 and the sensing data line 195 exists in a permitted range. However, the distance between the common electrode 270 formed on the test spacer 242 and the pressure sensor test line 193 that faces the test spacer 242 decreases by the height of the second height difference portion 158, and the distance becomes substantially “0 Å”, or in other words, there is not a space between the common electrode formed on the test spacer 242 and the pressure sensor test line 193. Thereby, the common electrode 270 and the pressure sensor test line 193 maintain a contact state without external pressure.

At this time, by adjusting the distance between the common electrode 270 on the test spacer 242 and the pressure sensor test line 193, the optimum distance between the common electrode 270 on the contact sensing protrusion 240 and the sensing data line 195 is defined. That is, when the distance between the common electrode 270 on the test spacer 242 and the pressure sensor test line 193 is substantially “0 Å”, the heights of the first to second height difference portions 128a and 128b, 158, are considered to maintain the optimum distance between the contact sensing unit protrusion 240 and the sensing data line 195.

The distance between the common electrode 270 on the test spacer 241 and the opposite pressure sensor test line 192 decreases by the height of the second height difference portion 158, and the third and fourth height difference portions 168 and 178. Thereby, the distance between the common electrode 270 on the test spacer 241 and the pressure sensor test line 192 is less than the height of the test spacer 241, and thereby the common electrode 270 on the test spacer 241 and the pressure sensor test line 192 contact. However, the common electrode 270 on the test spacer 241 hardly presses the pressure sensor test line 192 due to the insufficient space between the common electrode 270 and the sensing unit test line 192.

At this time, by adjusting the distance between the common electrode 270 on the test spacer 241 and the opposite pressure sensor test line 192, the maximum allowable distance between the contact sensing protrusion 240 and the sensing data line 195 is defined. That is, until the contact between the common electrode 270 on the test spacer 241 and the pressure sensor test line 192 is released as the distance there between become far, it is determined that the distance between the common electrode 270 on the contact sensing protrusion 240 and the sensing data line 195 is maintained in the allowable range.

An alignment layer (not shown) for aligning liquid crystal molecules in the liquid crystal layer 3 is coated on an inner surface of the display panels 100 and 200. The alignment layer may be a vertical alignment layer. Polarizers (not shown) are formed on an outer surface on the display panels 100 and 200. At least one of the polarizers may be omitted in a reflective LCD.

An LCD according to an exemplary embodiment of the present invention may further include a phase retardation film (not shown) for phase compensation of the LC layer 3. The LCD may further include a backlight unit (not shown) for supplying light to the polarizers, the phase retardation film, and the LC layer 3 between the display panels 100 and 200.

For testing the pressure sensors SU using the VI lines 521-523 according to an exemplary embodiment of the preset invention, a pressure sensor testing unit including the test spacers 241-243, the switching elements Q1-Q3, and the pressure sensor test lines 192-193 connected thereto, and the height difference portions 128a, 128b, 158, 168, and 178, etc., may be formed for every pressure sensor in the display area P1 of the LCD or may be formed for a predetermined number of the pressure sensors SU. As shown in FIGS. 6 and 12, a plurality of the pressure sensor test units may be formed adjacent to the pressure sensors SU in the edge region P2 of the LCD. In this case, portions of the sensing units SU may be formed on the edge region P2. The number of pressure sensors SU may be adjusted in consideration of reliability of the testing.

Now, the display and sensing operations of the above-described LCD will be described in detail.

The signal controller 600 is supplied with input image signals R, G, and B and input control signals for controlling the display thereof from an external graphics controller (not shown). The input image signals R, G, and B contain luminance information of the pixels PX, and the luminance has a predetermined number of grays, for example 1024 (=2¹⁰), 256 (=2⁸), or 64 (=2⁶) grays. Examples of the input control signals include a vertical synchronization signal Vsync, a horizontal synchronization signal Hsync, a main clock signal MCLK, and a data enable signal DE.

On the basis of the input control signals and the input image signals R, G, and B, the signal controller 600 generates image scanning control signals CONT1 and image data control signals CONT2, and it processes the image signals R, G, and B to be suitable for the operation of the panel assembly 300 and the image data driver 500. The signal controller 600 sends the image scanning control signals CONT1 to the image scanning driver 400, and sends the processed image signals DAT and the image data control signals CONT2 to the image data driver 500.

The image scanning control signals CONT1 include a scanning start signal STV for instructing to start scanning and at least one clock signal for controlling the output period of the gate-on voltage Von. The scanning control signals CONT1 may include an output enable signal OE for defining the duration of the gate-on voltage Von.

The image data control signals CONT2 include a horizontal synchronization start signal STH for informing of start of data transmission for a row of pixels PX, a load signal LOAD for instructing to apply the image data voltages to the image data lines D₁-Dₘ, and a data clock signal HCLK. The image data control signal CONT2 may further include an inversion signal RVS for reversing the polarity of the image data voltages (relative to the common voltage Vcom).

Responsive to the image data control signals CONT2 from the signal controller 600, the image data driver 500 receives a packet of the digital image signals DAT for the row of pixels PX from the signal controller 600, converts the digital image signals DAT into analog image data voltages selected from the gray voltages, and applies the analog image data voltages to the image data lines D₁-Dₘ.

The image scanning driver 400 applies the gate-on voltage Von to an image scanning line G₁-Gₙ in response to the scanning control signals CONT1 from the signal controller 600, thereby turning on the switching transistors Q connected thereto. The image data voltages applied to the image data lines D₁-Dₘ are then supplied to the pixels PX through the activated switching transistors Q.

The difference between the voltage of an image data voltage and the common voltage Vcom applied to a pixel PX is represented as a voltage across the LC capacitor Clc of the pixel PX, which is referred to as a pixel voltage. The LC molecules in the LC capacitor Clc have orientations depending on the magnitude of the pixel voltage, and the molecular orientations determine the polarization of light passing through the LC layer 3. The polarizer(s) converts light polarization to light transmittance such that the pixel PX has a luminance represented by a gray of the image data voltage.

By repeating this procedure by a unit of a horizontal period (also referred to as “1H” and is equal to one period of the horizontal synchronization signal Hsync and the data enable signal DE), all image scanning lines G₁-Gₙ are sequentially supplied with the gate-on voltage Von, thereby applying the image data voltages to all pixels PX to display an image for a frame.

When the next frame starts after one frame finishes, the inversion signal RVS applied to the image data driver 500 is controlled such that the polarity of the image data voltages is reversed (which is referred to as “frame inversion”). The inversion signal RVS may be also controlled such that the polarities of the image data voltages flowing in an image data line D₁-Dₘ are periodically reversed during one frame (for example row inversion and dot inversion), or the polarity of the image data voltages in one packet are reversed (for example column inversion and dot inversion).

The sensing signal processor 800 generates a digital sensing signal DSN corresponding to X-axis and Y-axis contact positions of the pressure sensor SU that is connected to the sensing data lines SY₁-SY_{N} and SX₁-SX_{M} by processing such as amplifying, filtering, etc. a sensing data signal flowing through the sensing data lines SY₁-SY_{N} and SX₁-SX_{M}. The sensing signal processor 800 then transfers the signal DSN to the contact determiner 700.

The contact determiner 700 receives the digital sensing signal DSN and, by using the digital sensing signal DSN, determines a contact position of the pressure sensor SU. The contact determiner 700 may then control an operation corresponding to a command, a menu, or another task that is selected by a user.

Now, an exemplary VI testing method of the pressure sensors in the exemplary LCD will be described.

First, with reference to FIG. 6, an inspector applies test signals to the VI lines 521-523 through the test pads VP1-VP3, respectively, and thereby tests the states of the red pixels RP, the green pixels GP, and blue pixels BP. At this time, a signal that turns off the switching elements Q1-Q3 is applied to the switching elements Q1-Q3 through the test pad SP connected to the test signal input line 531 for preventing interference due to the switching elements Q1-Q3, and thereby the VI testing of the pixels PX is stably operated.

That is, test signal voltages, each of which has a predetermined magnitude, are applied to the test pads VP1-VP3 using a separate test device (not shown), and thereby the test signals are transmitted to the image data lines of the red pixels RP, the green pixels GP, and the blue pixels BP connected to the VI lines 521-523, respectively. At this time, image scanning signals are applied to the image scanning lines G₁-Gₙ through a separate test pad (not shown).

Thereby, the red pixels RP, the green pixels GP, and the blue pixels BP operate, and the inspector inspects the display state such as the brightness of each pixel PX to determine the operating state of the pixels RP, GP, and BP, the disconnection of the corresponding image data lines LD, etc.

Next, the inspector stops the application of the test signals applied to the test pads VP1-VP3, and thereby the test pads VP1-VP3 are in a floating state.

Then, the inspector applies a signal for turning on the switching elements Q1-Q3 through the test pad SP via the test signal input line 531, and inspects the non-operation states of the pixels RP, GP, and BP. At this time, image scanning signals are applied to the image scanning lines G₁-Gₙ through the separate test pad (not shown), and the common electrode 270 formed on the test spacers 241-243 is supplied with a common voltage Vcom.

When the green pixels GP and the blue pixels BP connected to the VI lines 522 and 523 represent the corresponding colors, the inspector determines that the distance between the contact test protrusion 240 and the sensing data line 195 is maintained within the allowable range. Thereby, the inspector determines that the pressure sensors SU are normal.

However, when all of the red pixels RP, the green pixels GP, and the blue pixels BP connected to the VI lines 521-523 do not operate, the inspector determines that the distance between the contact test protrusion 240 and the sensing data line 195 exceeds the allowable maximum range by the release of contact between the test spacer 241 and the test line 192. Thereby, the inspector determines that the pressure sensors SU are abnormal.

When all of the red pixels RP, the green pixels GP, and the blue pixels BP operate, the inspector determines that the test spacer 243 contacts the test line 194, and thereby the distance between the contact sensing protrusion 240 and the sensing data line 195 exceeds the allowable minimum range. Thereby, the inspector determines that the pressure sensors SU are abnormal.

As described above, when the testing of the pressure sensors is finished, the image data lines LD connected to the VI lines 521-523 are cut along a cutting line L using, for example, a laser trimming device. At this time, when the single chip 610 is mounted, portions of the image data lines LD positioned under the single chip 610 are cut.

Using the height difference portions 128a, 128b, 158, 168, and 178, and the insulative layer 140 and the passivation layer 180 formed along with the pixels PX without an additional process, the operation states of pressure sensors SU are determined by adjusting the allowable range to the distance d between the contact test protrusions 240 and the sensing data lines 195.

Since, for testing the operations of the pixels RP, GP, and BP, the signals testing the pressure sensors SU are outputted through the VI lines 521, 522, and 523 that are already formed, it is unnecessary to further form separate test lines for testing the pressure sensors SU. In addition, the pixels RP, GP, and BP are used for inspecting the pressure sensors SU without a separate test device.

In an exemplary embodiment, the pressure sensors SU are inspected by connecting the VI lines 521-523 to the image data lines LD through the switching elements Q1-Q3, but the pressure sensors SU may be inspected by connecting the test line connected to the image scanning lines G₁-Gₙ to the switching elements Q1-Q3.

In exemplary embodiments of the present invention, an LCD is described as one example of the display device, but the above description may be applied to other display devices, such as a plasma display device, an organic light emitting diode (“OLED”) display, etc.

According to exemplary embodiments of the present invention, the test result of the pressure sensors is determined through the pixels, and thereby a separate device for determining the test result of the pressure sensors is unnecessary. Therefore, the test cost decreases and the test operation becomes easier.

The allowable distance between the contact sensing protrusion and the sensing data line is defined by forming a plurality of height difference portions when manufacturing the TFT array panel, so the manufacturing cost does not increase and an additional manufacturing process is unnecessary.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a first substrate having a plurality of test spacers; and
a second substrate having a plurality of sensing unit test lines facing the test spacers, respectively,
wherein surface heights of the sensing unit test lines are different from each other.

2. The display device of claim 1, wherein the test spacers have a same height as each other.

3. The display device of claim 1, wherein the second substrate further comprises a plurality of height difference portions formed under the sensing unit test lines, and a number of height difference portions formed under the sensing unit test lines is different for different sensing unit test lines.

4. The display device of claim 3, wherein the test spacers comprise first to third test spacers,
the sensing unit test lines comprise first to third sensing unit test lines facing the first to third test spacers, respectively,
the height difference portions comprise first to third height difference portions,
the first height difference portion is formed under the first sensing unit test line,
the first and second height difference portions are formed under the second sensing unit test line, and
the first to third height difference portions are formed under the third sensing unit test line.

5. The display device of claim 4, wherein the first substrate further comprises a conductor formed on the test spacers, and a distance between a surface of the conductor formed on the first test spacer and a surface of the first sensing unit test line is larger than 0 Å.

6. The display device of claim 5, wherein a distance between a surface of the conductor formed on the second test spacer and a surface of the second sensing unit test line is substantially 0 Å.

7. The display device of claim 5, wherein a distance between a surface of the conductor formed on the third test spacer and a surface of the third sensing unit test line is substantially 0 Å.

8. The display device of claim 4, wherein the first substrate further comprises a contact sensing protrusion formed adjacent to the test spacers,
the second substrate further comprises a sensing data line facing the contact test protrusion, and
a surface height of the sensing data line is substantially the same as one of the surface heights of the sensing unit test lines.

9. The display device of claim 8, wherein the surface height of the sensing data line is substantially the same as the surface height of the first sensing unit test line.

10. The display device of claim 8, wherein the second substrate further comprises a fourth height difference portion formed under the sensing data line.

11. The display device of claim 10, wherein the fourth height difference portion is formed on a same layer of the second substrate as the first height difference portion.

12. The display device of claim 8, wherein a height of the contact sensing protrusion is the same as heights of the test spacers.

13. The display device of claim 4, wherein the second substrate further comprises:
a plurality of image scanning lines;
an insulating layer formed on the image scanning lines and the first height difference portion;
a semiconductor layer formed on the insulating layer;
a plurality of image data lines on the semiconductor layer; and
a passivation layer formed on the image data lines, the third height difference portion, an exposed portion of the second height difference portion, and an exposed portion of the insulating layer.

14. The display device of claim 13, wherein the first height difference portion is formed on a same layer of the second substrate as the image scanning line.

15. The display device of claim 14, wherein the second height difference portion is formed on a same layer of the second substrate as the semiconductor layer.

16. The display device of claim 14, wherein the third height difference portion is formed on a same layer of the second substrate as the image data lines.

17. The display device of claim 13, wherein a thickness of the passivation layer formed under the first to third sensing unit test lines is substantially equal.

18. The display device of claim 4, wherein the second substrate further comprises a fourth height difference portion formed on the second height difference portion and an ohmic contact formed on the semiconductor layer, and the fourth height difference portion and the ohmic contact are formed within a same layer of the second substrate.

19. The display device of claim 18, wherein the fourth height difference portion and the third height difference portion have a same boundary.

20. The display device of claim 1, wherein the second substrate further comprises:
a plurality of signal transmitting units connected to the sensing unit test lines, respectively;
a signal input line supplied with a control signal controlling the signal transmitting units from an external device; and
a plurality of pixel test lines connected to the signal transmitting units, respectively,
wherein the display device further comprises a plurality of pixels connected to the pixel test lines.

21. The display device of claim 20, wherein pixels representing a same color are connected to a same pixel test line.

22. The display device of claim 20, wherein the signal input line comprises a first pad inputting the control signal, and the pixel test lines comprise second test pads inputting pixel test signals from an external device, respectively.

23. A liquid crystal panel assembly comprising:
a plurality of test spacers:
a plurality of sensing unit test lines facing the respective test spacers;
a plurality of signal transmitting units connected to the sensing unit test lines, respectively;
a signal input line that is supplied with a control signal controlling the signal transmitting units from an external device;
a plurality of pixel test lines connected to the signal transmitting units, respectively; and
a plurality of pixels connected to the pixel test lines,
wherein surface heights of the sensing unit test lines are different from each other.

24. The liquid crystal panel assembly of claim 23, wherein the test spacers have a same height.

25. The liquid crystal panel assembly of claim 23, further comprising a plurality of height difference portions formed under the sensing unit test lines, whereina number of height difference portions formed under the sensing unit test lines is different for different sensing unit test lines.

26. The liquid crystal panel assembly of claim 25, wherein the test spacers comprise first to third test spacers,
the sensing unit test lines comprise first to third sensing unit test lines facing the first to third test spacers, respectively,
the height difference portions comprise first to third height difference portions,
the first height difference portion is formed under the first sensing unit test line,
the first and second height difference portions are formed under the second sensing unit test line, and
the first to third height difference portions are formed under the third sensing unit test line.

27. The liquid crystal panel assembly of claim 26, wherein the liquid crystal panel assembly further comprises a conductor formed on the test spacers, and a distance between a surface of the conductor formed on the first test spacer and a surface of the first sensing unit test line is larger than 0 Å.

28. The liquid crystal panel assembly of claim 26, wherein a distance between a surface of the conductor formed on the second test spacer and a surface of the second sensing unit test line is substantially 0 Å.

29. The liquid crystal panel assembly of claim 26, wherein a distance between a surface of the conductor formed on the third test spacer and a surface of the third sensing unit test line is substantially 0 Å.

30. The liquid crystal panel assembly of claim 26, further comprising:
a contact sensing protrusion formed adjacent to the test spacers;
a sensing data line facing the contact sensing protrusion; and
a surface height of the sensing data line is substantially the same as one of the surface heights of the sensing unit test lines.

31. The liquid crystal panel assembly of claim 30, wherein the surface height of the sensing data line is substantially the same as the surface height of the first sensing unit test line.

32. The liquid crystal panel assembly of claim 30, further comprising a fourth height difference portion formed under the sensing data line.

33. The liquid crystal panel assembly of claim 32, wherein the fourth height difference portion is formed on a same layer of the liquid crystal panel assembly as the first height difference portion.

34. The liquid crystal panel assembly of claim 30, wherein a height of the contact sensing protrusion is the same as a height of the test spacers.

35. The liquid crystal panel assembly of claim 23, wherein pixels representing a same color are connected to a same pixel test line.

36. The liquid crystal panel assembly of claim 23, wherein the signal input line comprises a first pad inputting the control signal,
the pixel test lines comprise second test pads inputting pixel test signals from an external device, respectively, and
the first and second test pads are formed on an exposure region of the liquid crystal panel assembly.

37. The liquid crystal panel assembly of claim 23, wherein the sensing unit test lines and the signal transmitting units are formed on an edge region of the liquid crystal panel assembly.

38. The liquid crystal panel assembly of claim 23, wherein the signal transmitting units are switching elements.

39. The liquid crystal panel assembly of claim 23, further comprising a cutting line separating the connection between the pixels and the pixel test lines.

40. A testing method of a display device, the display device comprising a plurality of test spacers, a plurality of sensing unit test lines facing the test spacers, respectively, and having different surface heights from each other, a plurality of switching elements respectively connected to the sensing unit test lines, signal input lines supplied with a control signal from an external device to control the switching elements, a plurality of pixel test lines connected to the switching elements, and a plurality of pixels connected to the pixel test lines, the method comprising:
applying a signal turning off the switching elements to the signal input lines;
applying first test signals to the pixel test lines to test the pixels;
stopping application of the first test signals and applying a signal turning on the switching elements to the signal input lines;
testing the pixels; and
cutting connection between the pixels and the pixel test lines.
